(19) United States
(12) Patent Application Publication
(10) Pub. No.: US 2008/0142076 A1
(43) Pub. Date: Jun. 19, 2008

(54) Chamber for housing an energy-conversion unit

(75) Inventors: Stephen Horne, El Granada, CA (US); Mark Spencer, San Jose, CA (US)

Correspondence Address: HAVERSTOCK & OWENS LLP, 162 N WOLFE ROAD, SUNNYVALE, CA, 94086, US

(73) Assignee: Sol Focus, Inc.

(21) Appl. No.: 11/639,564

(22) Filed: Dec. 15, 2006

(51) Int. Cl. H01L 31/04; B32B 37/00

(52) U.S. Cl. 136/259; 156/60; 156/327

(57) ABSTRACT

Embodiments of the present invention seal an inside volume of an energy conversion unit from the outside atmosphere. A chamber for housing an energy conversion unit includes a lid having a first rim, a housing having a second rim, and a continuous seal sealing the first rim to the second rim. The lid and the housing form a volume with an atmosphere for securely housing an energy conversion unit. The seal has sidewalls that extend from the first rim to the second rim and includes an embedded ribbon that extends along a length of the seal such that the atmosphere is controlled by the continuous seal. Preferably, the embedded ribbon oscillates between the sidewalls in a pattern, such as a wave, a square wave, or a zig-zag. Preferably, the energy conversion unit is a concentrator photovoltaic device that includes optics for focusing light onto a photo-sensitive area of the photovoltaic device.

### FIELD OF THE INVENTION

This invention relates to chambers for housing energy-conversion units. More specifically, this invention relates to chambers that hermetically seal light-to-electrical conversion units.

### BACKGROUND OF THE INVENTION

As their efficiency increases, energy conversion units are becoming more cost effective and attractive sources of energy. A light-to-electrical conversion unit takes solar energy and converts it into electricity for use in homes and businesses. Some light-to-electrical conversion units have efficiencies of at least 35%, and that number is increasing. By tracking the sun, these units can convert light to electricity during a large portion of the day.

A light-to-electrical conversion unit has components that are sensitive to moisture and, accordingly, is enclosed in a sealed volume that protects it from the outside atmosphere. The unit includes optics that guide incoming light to a receiving area of the light-to-electrical conversion unit. When moisture forms on an element that focuses the light onto the receiving area in a solar concentrator system, the light is no longer accurately focused thereon. When this focus deviates by even a small amount, the efficiency of the light-to-electrical conversion unit drops. A few millimeter deviation can quickly reduce the efficiency of the light-to-electrical conversion unit from 500 suns to a fraction of that amount.

Moisture within the volume results in other problems, such as the diffusion into semiconductor devices and the corrosion of electrical leads and other metal parts. Pressure differentials between a volume containing a light-to-electrical conversion unit and the outside atmosphere place undue pressure on seals and other components in the volume. Preventing the leakage of moisture and contaminants into the volume and reducing pressure fluctuations between the volume and an outside atmosphere are thus goals for light-to-electrical conversion units.

### SUMMARY OF THE INVENTION

Embodiments of the present invention seal an inside volume of an energy conversion system from moisture and outside contaminants. In a first aspect of the present invention, a chamber for housing an energy conversion unit includes a lid having a first rim, a housing having a second rim, and a continuous seal for sealing the first rim to the second rim. The lid and the housing form a volume with an atmosphere for securely housing an energy conversion unit. The seal has sidewalls that extend from the first rim to the second rim and includes an embedded ribbon that extends along a length of the seal such that the atmosphere is controlled by the continuous seal. Preferably, the embedded ribbon is formed in an oscillating pattern to provide structural stability between the sidewalls, such as a smoothly curving wave, a square wave, or a zig zag. The seal includes the embedded ribbon and butyl rubber adhesive layers that couple the seal to the first and second rims.

In one embodiment, the first and second rims form a flange and the ribbon is formed of a metal. Preferably, the metal is aluminum, the sidewalls are a plastic, the lid is formed of glass, and the housing is formed of a metal.

In another embodiment, the chamber also includes a convex mirror coupled to the lid, a concave mirror coupled to the lid and enclosing the convex mirror, and an energy conversion unit contained in the volume. The mirrors and conversion unit are aligned in an optical path from the lid to the concave mirror, from the concave mirror to the convex mirror, and from the convex mirror to the energy conversion unit. Preferably, the energy conversion unit is a light-to-electrical conversion unit.

In accordance with a second aspect of the present invention, a method of forming an energy conversion structure includes positioning an energy conversion unit within a volume of a housing having a second rim, such that the volume has an inside atmosphere; positioning a lid having a first rim so that the first rim aligns with the second rim; and forming a seal between the first rim and the second rim so that the inside atmosphere is contained by the seal. The seal has sidewalls that extend from the first rim to the second rim and contains an embedded ribbon that extends along a length of the seal. Preferably, the energy conversion unit is a light-to-electrical conversion unit, such as a photovoltaic cell. In one embodiment, the seal includes a first rubber layer that couples the seal to the first rim and a second rubber layer that couples the seal to the second rim. The embedded ribbon oscillates between the sidewalls in a pattern such as a wave, a square wave, or a zig zag.

In one embodiment, the seal is formed by heating the first and second rubber layers to a bonding temperature while the seal is in contact with the first and second rims. The first and second rubber layers both include butyl rubber, and the bonding temperature is at least 50° C.

In one embodiment, the method also includes forming a third rubber layer on the lid and a fourth rubber layer on the housing. The method also includes pressing the first and third rubber layers until they fuse together and pressing the second and fourth rubber layers until they also fuse together. The first, second, third, and fourth rubber layers all include butyl rubber.

In one embodiment, the method also includes forming a layer of silicon adjacent to a wall of the seal opposite the volume, thereby sealing the wall from an outside atmosphere.

In a third aspect of the invention, a chamber for housing a light-to-electrical conversion unit includes a housing that has a first element and a second element, an optical system coupled to the housing, and a continuous rubber seal for sealing the first element to the second element. The first and second elements together form a volume containing a light-to-electrical conversion unit. The first and second elements also define a shear plane. The optical system focuses light beams onto the light-to-electrical conversion unit. The continuous rubber seal includes an embedded wall that oscillates in a plane parallel to the shear plane and extends along a length of the seal.

Preferably, the seal is formed of butyl rubber, and the embedded wall is formed of a metal, which is encased in a plastic.

In one embodiment, the chamber also includes a convex mirror coupled to the first element, a concave mirror coupled to the second element and enclosing the convex mirror, and a light-to-electrical conversion unit contained in the volume and aligned in an optical path from the first element to the concave mirror, from the concave mirror to the convex mirror, and from the convex mirror to the light-to-electrical conversion unit.

### BRIEF DESCRIPTION OF THE DRAWINGS

FIG. 1 is a side cross-sectional view of a chamber for housing a light-to-electrical conversion unit in accordance with the present invention.

FIG. 2 is a top view of multiple chambers, all similar to the chamber in FIG. 1, for converting light to electricity.

FIG. 3 is a top cross-sectional view of the chamber of FIG. 1, illustrating a seal in accordance with the present invention.

FIG. 4 is a front cross-sectional view of the seal in FIG. 1.

FIG. 5 is a side cross-sectional view of the chamber of FIG. 1, showing how the seal responds to a shear force.

FIG. 6 is a top cross-sectional view of the seal of FIG. 1, oscillating in a pattern in accordance with one embodiment of the present invention.

FIGS. 7A-D are top cross-sectional views of the seal of FIG. 1, having other patterns, all in accordance with other embodiments of the present invention.

FIG. 8 shows the steps of a process for forming an energy-conversion chamber, including forming a seal to enclose an energy-conversion unit, in accordance with the present invention.

FIG. 9A shows in detail the step of forming the seal of FIG. 8, in accordance with one embodiment of the present invention.

FIG. 9B shows in detail the step of forming the seal of FIG. 8, in accordance with another embodiment of the present invention.

FIGS. 10A-D show the elements of a chamber at each step of the process of FIG. 9A.

FIG. 11 is a high-level diagram of an energy-conversion unit with an environmental control module, in accordance with the present invention.

FIG. 12 is a high-level flow chart of steps for controlling an environment containing an energy-conversion unit in accordance with the present invention.

FIG. 13 shows the components of an energy-conversion unit having an internal bladder for controlling a pressure within a volume of the energy-conversion unit in accordance with the present invention.

FIG. 14 shows the components of an energy-conversion unit having a desiccant and valve arrangement for controlling a pressure and moisture within a volume of the energy-conversion unit in accordance with the present invention.

FIG. 15 shows the components of an energy-conversion unit having an inert gas source and valve arrangement for controlling pressures within the volumes of multiple energy-conversion units in accordance with the present invention.

FIG. 16 shows the components of an energy-conversion unit having a labyrintine tube for controlling pressures within a volume of an energy-conversion unit in accordance with the present invention.

### DETAILED DESCRIPTION OF A PREFERRED EMBODIMENT

Energy-conversion units, such as concentrator photovoltaic devices (both fresnel lens and mirror optic based structures), are generally enclosed within chambers that provide structure and protection from an outside environment. The outside environment contains moisture, dust and pollutants. Pressure fluctuations within these units can be caused by temperature changes, barometric pressure changes, and the like. Embodiments of the present invention maintain an inside volume of a chamber separate from outside moisture, from outside contaminants, from pressure fluctuations, or any combination of these. The pressure fluctuation of the outside environment is very minimal compared to the pressure fluctuation within a totally sealed chamber due to temperature changes within the chamber. Thus, embodiments of the invention are designed to keep the chamber pressure equal to (or within a small band of) the pressure of the outside environment.

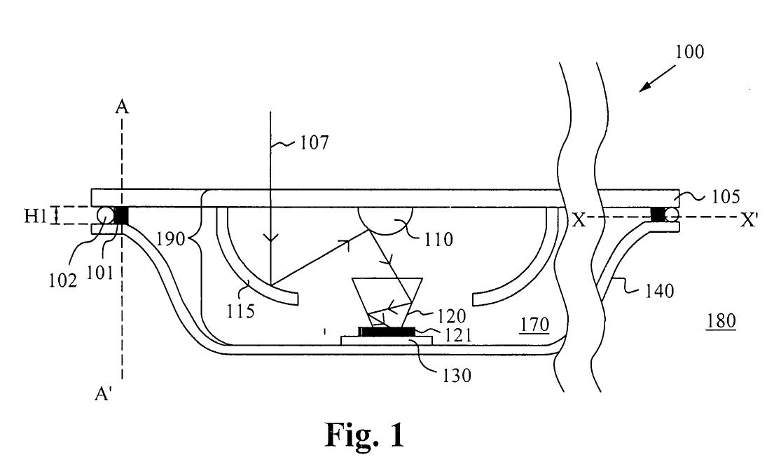

FIG. 1 is a side cross-sectional view of a chamber 100 (also referred to as a “converter”) containing a light-to-electrical conversion unit 130. In operation, light 107 follows an optical path from the sun, through a transparent lid 105 and to a concave mirror 115; the concave mirror 115 reflects the light onto a convex mirror 110, which reflects the light to a rod 120; using internal reflection, the rod 120 focuses the light through a translucent pad 121 and then onto a receiving area of a light-to-electrical unit 130 (e.g., a “solar cell” or a “photovoltaic cell”). The light-to-electrical unit 130 converts the light into electrical energy, such as a current or a voltage, which is then transmitted to an electrical load, such as a motor, electronic device, or even a battery for storing the energy for later use. To simplify the illustration, FIG. 1 does not show the chamber 100 coupled to an electrical load or battery.

In one embodiment, the light-to-electrical conversion unit 130 is a triple-junction conversion cell, such as one containing a gallium-indium phosphide diode, for converting light in the blue portion of the light spectrum, a gallium arsenide diode, for converting light in the green portion of the light spectrum, and a germanium diode, for converting light in the red portion of the light spectrum. It will be appreciated, however, that other types of conversion cells are able to be used in accordance with the present invention.

As shown in FIG. 1, the chamber 100 defines a volume 170 for housing the mirrors 110 and 115, the rod 120, the pad 121, and the light-to-energy unit 103. A first seal 101 and an optional second seal 102 seal the lid 105 to the housing 140, sealing the inside volume 170 and its atmosphere from an outside atmosphere 180 external to the chamber 100. The first seal 101 and the optional second seal 102 thus prevent moisture, dust, pollution, and other contaminants from leaking from the outside atmosphere 180 into the volume 170.

Preferably, the lid 105 is made of glass, the housing 140 is made of a metal, such as aluminum or steel, the pad 121 is made of silicone, and the seal 102 is a silicone adhesive. The seal 101 spaces the lid 105 from the housing 140 a distance H1. In one embodiment, H1 is approximately 8 mm, but those skilled in the art will recognize many other possible values for H1. The material and structure of the seal 101 are described below.

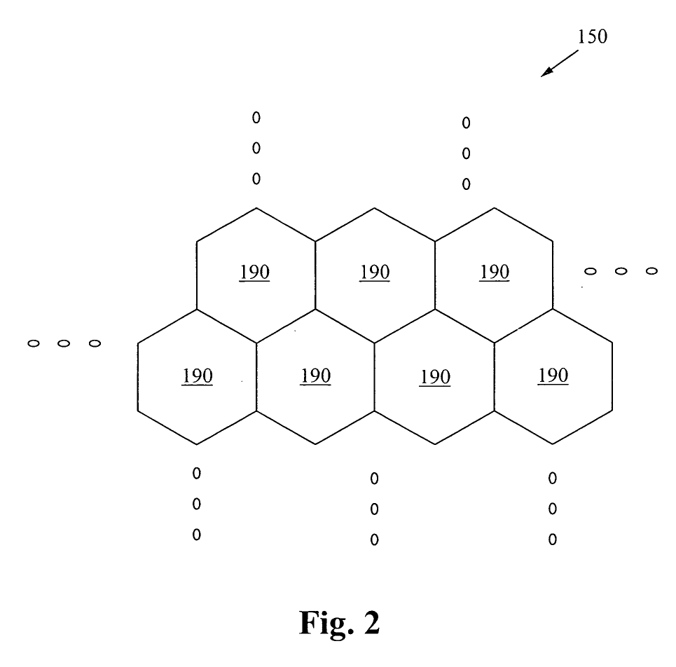

To simplify the discussion that follows, the light-to-electrical conversion unit 130, the pad 121, the rod 120, the mirrors 115 and 110, and the portion of the lid 105 overlying the mirror 115 are together referred to as a “concentrator unit” 190. In a preferred embodiment, more than one concentrator unit is contained within a single housing 100. Preferably, the electrical energy generated by all the concentrator units in a single housing is combined. Moreover, to generate additional energy, chambers such as the chamber 100 are ganged and their combined electrical energy is transmitted to a load or battery. FIG. 2, for example, is a top view of a combination 150 of exemplary concentrator units 190 contained in a single housing. As shown in FIG. 2, the top cross-sectional area of each of the concentrator units 190 has a hexagonal shape, and the combination 150 has a honeycomb pattern. Those skilled in the art will recognize many other shapes for the lid 105 and combination 150 of concentrator units. Those skilled in the art will also recognize that while FIG. 2 shows multiple concentrator units 190 arranged in a honeycomb pattern, embodiments of the present invention can include a single concentrator unit in a housing.

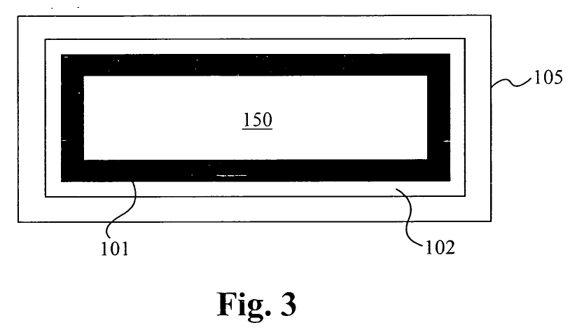

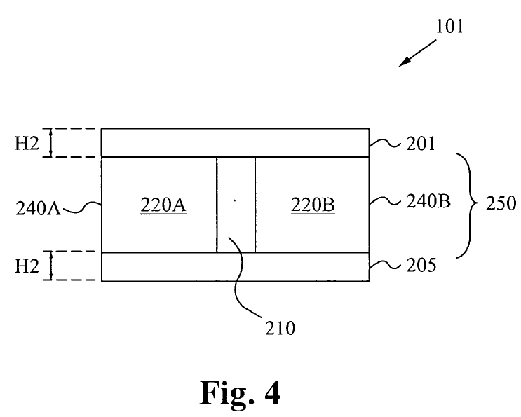

FIG. 3 is a top cross-sectional view of the chamber 100 along the line X-X′ of FIG. 1 across the entire width of the chamber 100. To simplify the drawing, the cross-sectional view does not include the mirrors 110 and 115. FIG. 4 is a side cross-sectional view of the seal 101 along the line A-A′ of FIG. 1, in a plane perpendicular to the page. The seal 101 includes a top layer of rubber 201 that seals to a surface of the lid 105 and a bottom layer of rubber 205 that seals to a surface of the housing 140. The seal 101 also includes a ribbon 210 of material, preferably a metal, that extends from the top layer of rubber 201 to the bottom layer of rubber 205. As explained below, the ribbon 210 extends continuously along the length of the seal 101. Plastic sidewalls 240A and 240B are coupled to the edges of the top and bottom layers of the rubber 201 and 205, respectively. The ribbon 210 and the sidewall 240A define a first volume 220A, and the ribbon 210 and the sidewall 240B define a second volume 220B. Preferably, the first and second volumes 220B are air-filled, but they can be filled with sealing materials such as rubber. The elements 240A, 220A, 210, 220B, and 240B together are labeled 250 for easy reference below.

In a preferred embodiment, the top and bottom layers 201 and 205, respectively, are made of butyl rubber, and the sidewalls 240A and 240B are made of plastic. In light of the function of the seal 101 described below, those skilled in the art will recognize other suitable materials. The top and bottom layers of rubber 201 and 205 have a thickness H2. In one embodiment, H2 is approximately 0.3 mm, but those skilled in the art will recognize many other possible values for H2. Those skilled in the art will also recognize that the ribbon 210 can be made of materials other than metal that are impenetrable to moisture and vapor.

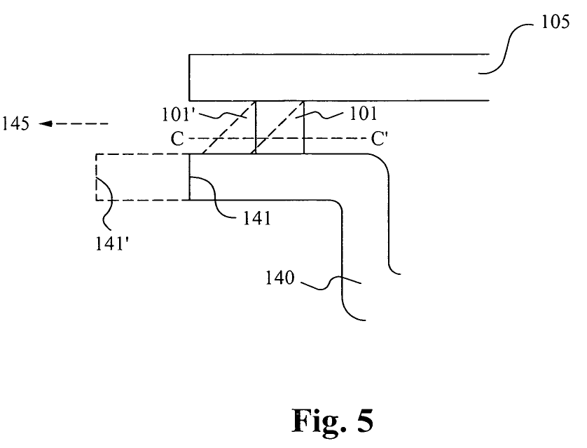

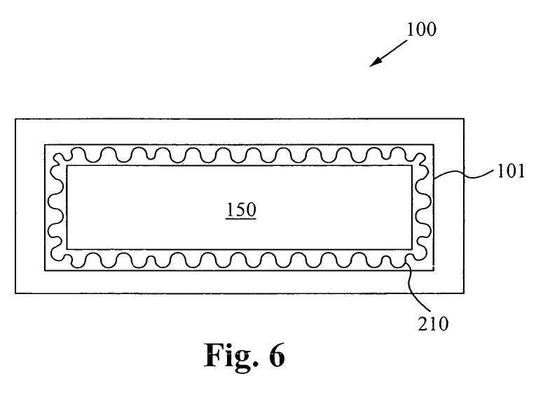

Referring to again to FIG. 1, the lid 105 can move relative to the housing 140 for many reasons, such as when the chamber 101 is being constructed, transported, or even serviced. Or, the lid 105 can move relative to the housing 140 because of the different rates of thermal expansion for the lid 105 and the housing 140 when the chamber 100 is exposed to heat or cold. FIG. 5 is a side cross-sectional view of a portion of the chamber 100. FIG. 5 shows that after the chamber 101 has been heated, the edge 141 of the housing 140 has moved from the position 141 to the position 141′. The seal 101 has correspondingly moved so that its configuration changes from the one labeled 101 to the one labeled 101′. A shear force, as shown by the arrow 145, is exerted on the seal 101, which, without the present invention, can cause it to irreversibly fail. The shear plane parallel to inner surfaces of the lid 105 and the housing 140 is defined by the segment C-C′ in a plane perpendicular to the page. FIGS. 5 and 6 (described below) illustrate that the ribbon 210 oscillates in a plane parallel to the shear plane C-C′. With this structure, the ribbon 210 (FIG. 4) counteracts this shear force, thus protecting the seal 101 against failure.

The ribbon 210 can have many different configurations for counteracting shear forces. One such configuration is illustrated in FIG. 6, a top cross-sectional view of the chamber 100 of FIG. 1, showing the seal 101 with an embedded ribbon 210. The embedded ribbon 210 extends along the entire length of the seal 101 and fully encloses the volume 170 containing the combination 150. The ribbon 210 oscillates between the sidewalls 240A and 240B, but never touches them. In other embodiments, the ribbon 210 does touch the sidewalls 240A and 240B. The oscillating pattern of the ribbon 210 also allows it to be easily bent to follow the contour of a rim of the lid 105 and the housing 140. One such seal, with an embedded oscillating ribbon, is a Squiggle® Seal, sold by Truseal Technologies of Solon, Ohio.

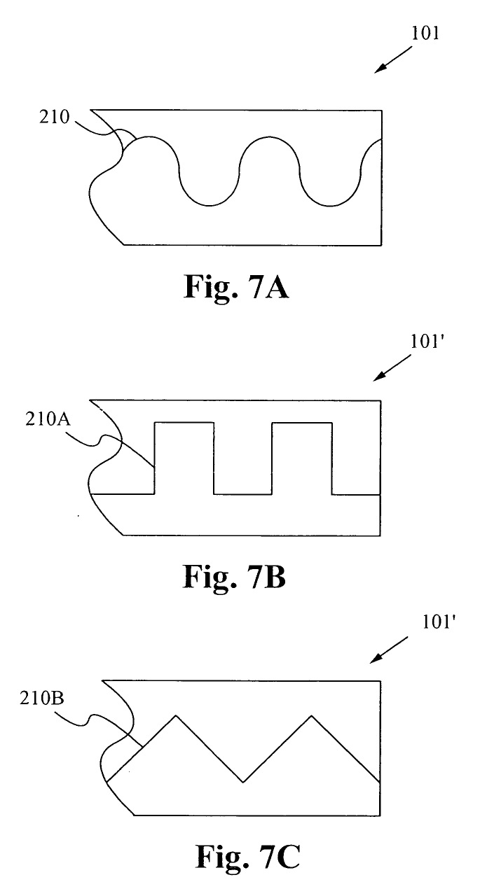

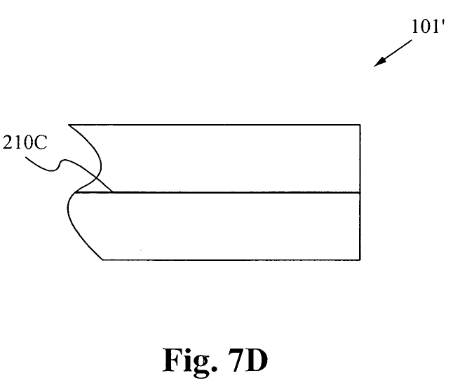

FIGS. 7B-D show a few other possible patterns for embedded ribbons in alternative seals 101′ in accordance with the invention. These include a square-wave pattern 210A (FIG. 7B), a zig-zag (e.g., saw-tooth) pattern 210B (FIG. 7C), and a non-oscillating, straight pattern 210C (FIG. 7D). Those skilled in the art will recognize other patterns that can be used in accordance with the present invention.

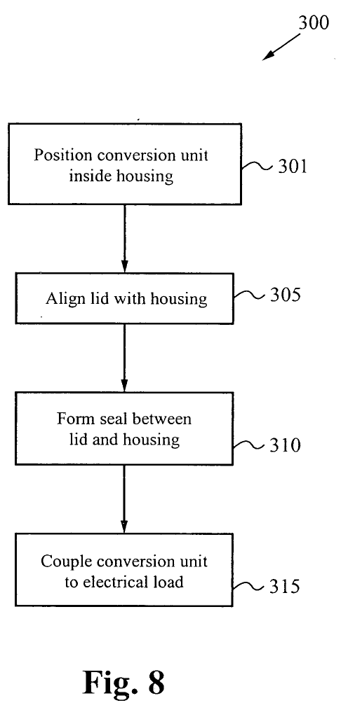

FIG. 8 shows the steps of a process 300 for constructing a chamber for housing one or more concentrator units, such as a light-to-electrical conversion unit, in accordance with the present invention. First, in the step 301, the energy-conversion unit is positioned inside a housing. Next, in the step 305, a lid is aligned with the housing, and in the step 310, a seal is formed between the lid and the housing. Preferably, the seal is formed between an outer edge or rim of the lid and a rim of the housing. Finally, in the step 315, the energy-conversion unit is coupled to a load. In alternative embodiments, different sealing surfaces of the lid and housing, surfaces other than the rims, are sealed together to form an enclosed volume.

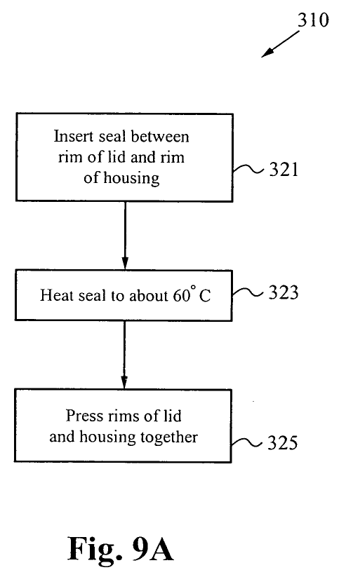

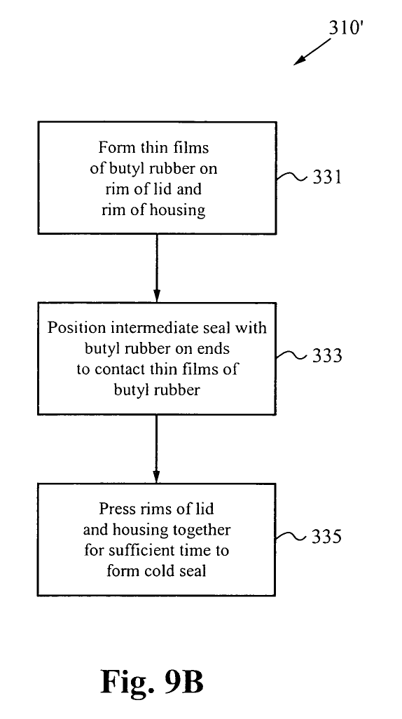

FIGS. 9A and B show more detailed elements of the step 310 according to different embodiments of the invention. Referring to FIGS. 1 and 9A, in the step 321, the seal 101 is inserted between the rim of the lid 105 and the rim of the housing 140. Next, in the step 323, the seal is heated to about 60° C., such as for the Squiggle® Seal product. Next, in the step 325, the rims of the lid 105 and the housing 140 are pressed together. Though shown as separate steps, the steps 323 can be performed together or during overlapping intervals.

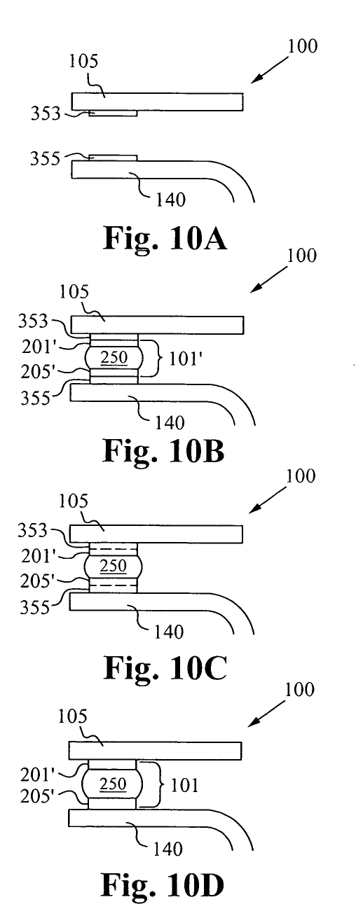

FIG. 9B shows the detailed elements of the step 310 according to an alternative embodiment, using a “cold sealing method,” and FIGS. 10A-D show the elements of the chamber 100 during each step. Referring to FIGS. 9B and 1A, in the step 331, a thin film of butyl rubber 353 is formed on an inner surface of the lid 105 and a thin film of butyl rubber 355 is formed on an inner surface of the housing 140. Next, referring to FIGS. 9B and 10B, in the step 333, an “intermediate” seal 101′ is placed between the thin films of butyl rubber 353 and 355. The seal 101′ is called intermediate because it is not the final seal 101 but fuses with the thin films of butyl runner 353 and 355 to form the final seal 101. The seal 101′ includes the portion 250 (see FIG. 4) and top and bottom layers of rubber 201′ and 205′, with structures similar to that of the layers 201 and 205 of FIG. 4. Next, referring to FIGS. 9B and 10C, the rims of the lid 105 and the housing 140 are pressed together. Next, referring to FIGS. 9B and 10D, after a sufficient time, the layer 353 fuses with the layer 201′ to form the layer 201 (FIG. 4), and the layer 355 fuses with the layer 205′ to form the layer 205.

As an extra, optional sealant, after the seal 101 is formed, the seal 102 is also formed between the seal 101 and the outside atmosphere, as shown in FIG. 1.

For comparison, experiments have shown that using prior art sealing methods, water leaks into an inside volume (e.g., 170 in FIG. 1) at a rate of about 150 g-per square meter-per day at 30° C. and 95% relative humidity. Using embodiments of the present invention, this rate was reduced to about 0.05 g-per square meter-per day at 30° C. and 95% relative humidity.

As described below, energy conversion units are also placed in environments in which the pressure of the outside atmosphere changes. Differentials between pressures in an inside volume and the outside atmosphere cause seals to fail. Embodiments of the present invention are configured to balance the inside and outside pressures, putting less stress on the seals, and thereby reducing the chance that they fail.

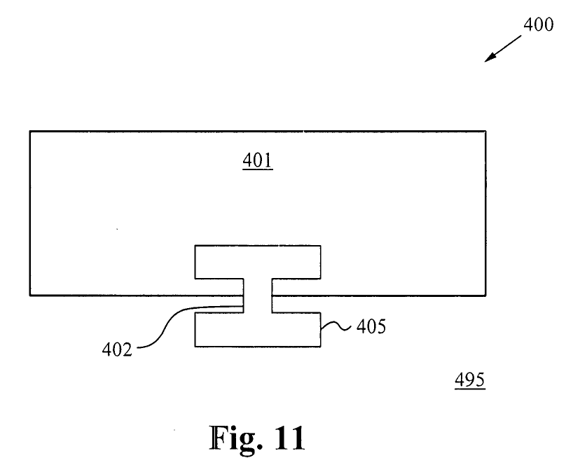

FIG. 11 is a high-level diagram of a chamber 400 for housing an energy conversion unit. The chamber 400 has a volume 401 (such as the volume 170 in FIG. 1) with an inside atmosphere. The inside atmosphere has a pressure and is sealed from an outside atmosphere 495 with its own, sometimes varying, pressure. Not shown in FIG. 11 are seals on the chamber 400, such as those that seal conduits running from the chamber to external loads and those for sealing a top lid to a housing, such as described above. The chamber 400 also includes an aperture 402 which is hermetically sealed to an environmental control unit 405 that extends from the volume 401 to the outside atmosphere 495 a counterbalances a pressure within the volume 401 with a pressure of the outside atmosphere 495 while still sealing the volume 401 from the outside atmosphere 495.

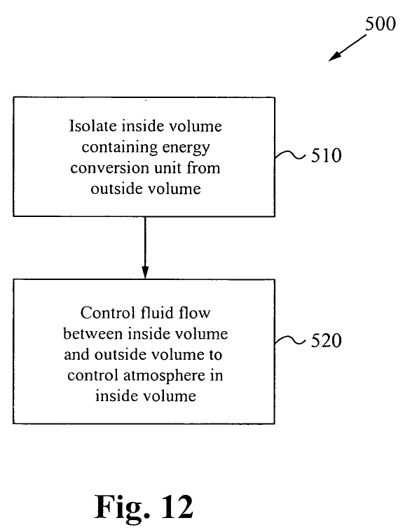

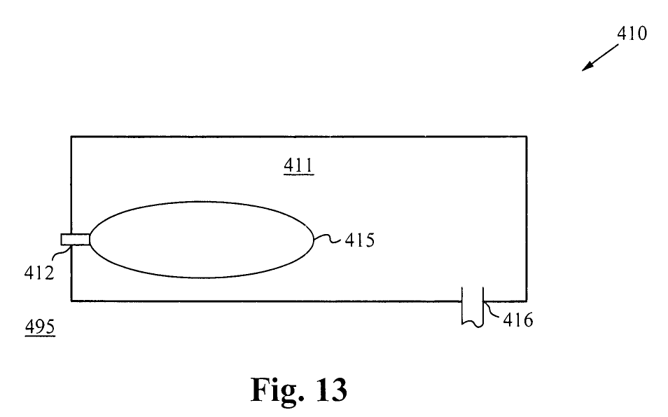

FIG. 12 is a high-level diagram of the steps of a process 500 for controlling an environment containing an energy-conversion unit, in accordance with the present invention. Specific structures for practicing these steps are shown in FIGS. 13-16.

In the first step 510 of the process 500, a first volume containing the energy-conversion unit is isolated from a second volume. The first volume is contained within a housing of a chamber, and the second volume is outside the housing. Next, in the step 520, a fluid flow between the first volume and the second volume is controlled to control an atmosphere of the first volume. As explained below, in this way fluid containing moisture and contaminants are prevented from flowing into the first volume, pressure differentials are minimized, and other advantages, either alone or in combination, are realized.

FIG. 13 is a diagram of a chamber 410 for housing an energy conversion unit and having an environmental control unit, here a bladder 415, that balances a pressure within a volume 411 (the “inside pressure”) of the chamber 410 with a pressure of the outside atmosphere 495 (the “outside pressure”). As shown in FIG. 13, the chamber 410 has an aperture 412 that couples the volume 411 with the outside atmosphere 495. The bladder 415 has an opening that hermetically seals to the aperture 412 so that the outside atmosphere 495 is fluidly connected to an inner cavity of the bladder 415 while maintaining the seal between the volume 411 and the outside atmosphere 495. The inner cavity of the bladder 415 is isolated from the volume 411. The chamber 410 also has a seal 416 that seals electronics inside the volume 411 with a load (not shown) external to the volume, as well as a seal between components such as a lid and housing that form the chamber 410.

In operation, when the outside pressure is larger than the inside pressure, air automatically flows into the cavity of the bladder 415, which expands. The inside and outside pressures differ negligibly, if at all, so that there is little, if any, pressure differential exerted on the seal 416. Alternatively, when the outside pressure is smaller than the inside pressure, air automatically flows from the cavity of the bladder 415 to the outside atmosphere 495, so that the bladder 415 contracts. Again, the inside and outside pressures are essentially balanced so that there is little, if any, pressure differential exerted on the seal 416. Pressure changes can result when temperatures inside the volume 411 heat up or cool down, or when the chamber 410 is taken to high altitudes.

Preferably, the bladder 415 is a stainless steel bellows or is made from aluminized Mylar™, aluminized rubber, or a phosphor bronze. The bladder 415 can also be made from many other different materials and composites of materials, such as a foil lined bag.

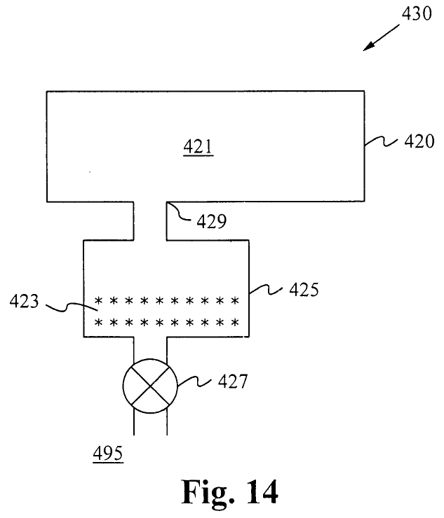

FIG. 14 shows a structure 430 for controlling an environment with a volume of a chamber 423 in accordance with another embodiment of the present invention. The structure 430 has a chamber 420 with a volume 421 and an aperture 429 that fluidly couples the volume 421 to a filter system 425. The filter system 425 is coupled to the outside atmosphere 495 by a flow limiter 427. In operation, the flow limiter 427 responds to differences between a pressure in the volume 421 (the “inside pressure”) and a pressure of the outside atmosphere 495 (the “outside pressure”). In one embodiment, the flow limiter 427 is a pressure differential valve configured to generate a fluid flow path from the outside atmosphere 495, through the filter system 425, and into the volume 421 when the inside pressure exceeds the outside pressure by a threshold value. In one embodiment, this threshold value is about 1 psi. Those skilled in the art will recognize other values for the threshold value.

To ensure that air traveling from outside atmosphere 495, through the filter system 425, and into the volume 421 does not contain moisture, the filter system 425 includes a drying agent 423, which removes moisture in the air before it enters the volume 421. Preferably, the drying agent 423 is a desiccant agent, such as one that includes a molecular sieve or an anhydrous salt. Alternatively, the desiccant agent includes an indicating silica gel for determining the moisture level within the desiccant. In other embodiments, the filter system 425 also filters particulate contaminants and thus also includes a particulate filter or an activated carbon bed.

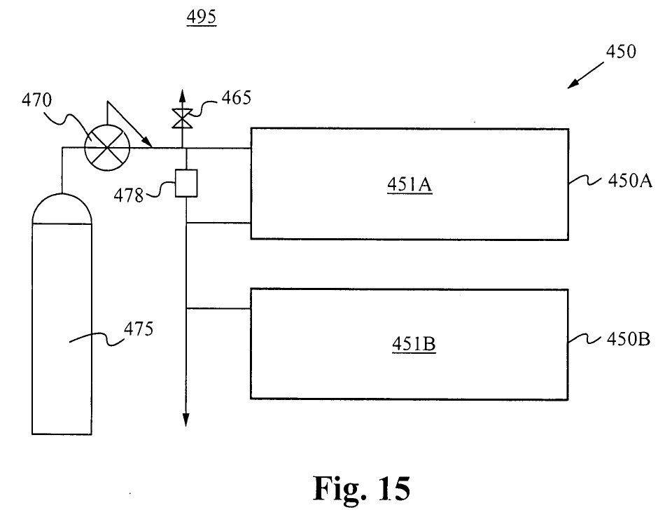

FIG. 15 shows a structure 460 for controlling the environments with the volumes of multiple chambers, only two of which are shown (450A and 450B), in accordance with another embodiment of the present invention. The structure 460 includes chambers 450A and 450B, having volumes 451A and 451B, respectively, all coupled to a manifold 478. The manifold 478 fluidly couples the volumes 451A and 451B through a forward pressure regulator 470 to a gas source 475. A pressure relief valve 465 couples the forward pressure regulator 470 and the manifold 478 to the outside atmosphere 495. The gas source 475 contains dry gas or an inert gas such as nitrogen, argon, or helium. The forward pressure regulator 470 is configured to maintain a difference between the pressures in the volumes 451A and 451B (the inside pressures) and a pressure of the outside atmosphere 495 (the outside pressure) below a predetermined value.

In operation, the gas source 475 continuously maintains a slight positive pressure differential between the inside pressures and the outside pressure, such as 0.125 psi. Thus, if any leakage occurs between a seal on a chamber (e.g., 450A and 450B), the slight positive pressure differential will force air out of, not into, the corresponding volume (451A or 451B). No moisture or contaminants will flow from the outside atmosphere 495 into any of the volumes 451A and 451B.

While FIG. 15 shows multiple chambers 450A and 450B, it will be appreciated that the structure of FIG. 15 can be used to control the environment of the volume of a single chamber.

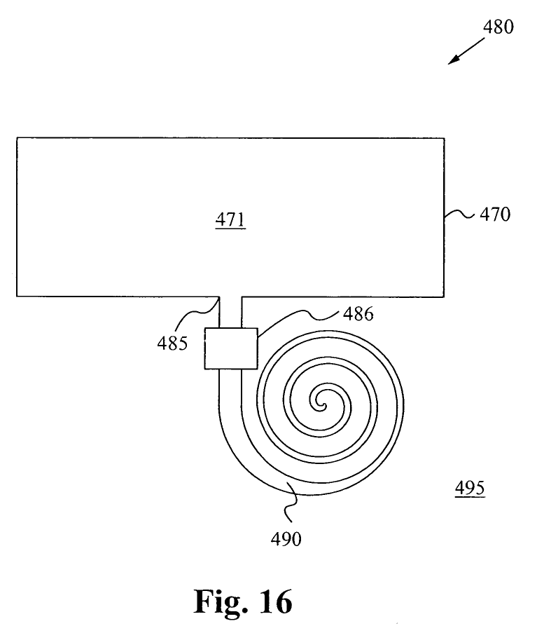

FIG. 16 shows a structure 480 configured to also limit the flow of air into a volume that houses an energy conversion unit in accordance with another embodiment of the present invention. The structure 480 includes a chamber 470 having a volume 471 coupled through an aperture or orifice 485 to a filter 486 and then to a labyrintine tube 490. The labyrintine tube 490 is configured to generate a flow path from the outside atmosphere 495, through the labyrintine tube 490, through the filter 486, and into the volume 471 when a pressure within the volume 471 differs from a pressure of the outside atmosphere 495. The filter 486 removes moisture and dust from air flowing from the outside atmosphere 495 before it flows into the volume 471. Preferably, the aperture 485 and the labyrintine tube 490 have a diameter, length, and porosity sufficient to limit gas diffusion from the outside atmosphere 495 into the volume 471 to less than 0.05 grams per day.

It will be appreciated that the while the structures in FIGS. 13-16 show only environmental control units coupled to chambers, it will be appreciated that elements of the present invention can be combined in different ways. For example, structures in accordance with the present invention have both seals, such as the seal 101 in FIG. 1, and also an environmental control unit, such as the bladder 415 in FIG. 13. Those skilled in the art will recognize many ways to combine the specific embodiments of the invention.

It will be readily apparent to one skilled in the art that other modifications may be made to the embodiments without departing from the spirit and scope of the invention as defined by the appended claims.

We claim:

1. A chamber for housing an energy conversion unit comprising:
a lid having a first rim;
a housing having a second rim, wherein the lid and the housing form a volume with an atmosphere for securely housing an energy conversion unit; and
a continuous seal sealing the first rim to the second rim, wherein the seal has sidewalls extending from the first rim to the second rim and includes an embedded ribbon that extends along a length of the seal such that the atmosphere is controlled by the continuous seal.

2. The chamber of claim 1, wherein the embedded ribbon oscillates between the sidewalls in a pattern.

3. The chamber of claim 1, wherein the seal comprises butyl rubber and the embedded ribbon.

4. The chamber of claim 2, wherein the pattern is one of a wave, a square wave, and a zig zag.

5. The chamber of claim 1, wherein the seal further comprises butyl rubber adhesive layers coupling the seal to the first and second rims.

6. The chamber of claim 1, wherein the first and second rims form a flange.

7. The chamber of claim 1, wherein the ribbon comprises a metal.

8. The chamber of claim 6, wherein the metal is aluminum and the sidewalls are a plastic.

9. The chamber of claim 1, wherein the lid comprises a glass and the housing comprises a metal.

10. The chamber of claim 8, further comprising:
a convex mirror coupled to the lid;
a concave mirror coupled to the lid and enclosing the convex mirror; and
an energy conversion unit contained in the volume and aligned in an optical path from the lid to the concave mirror, from the concave mirror to the convex mirror, and from the convex mirror to the energy conversion unit.

11. The chamber of claim 10, wherein the energy conversion unit is a light-to-electrical conversion unit.

12. A method of forming an energy conversion structure comprising:
positioning an energy conversion unit within a volume of a housing having a second rim, wherein the volume has an inside atmosphere;
positioning a lid having a first rim so that the first rim aligns with the second rim; and
forming a seal between the first rim and the second rim so that the inside atmosphere is contained by the seal, wherein the seal has sidewalls extending from the first rim to the second rim and contains an embedded ribbon that extends along a length of the seal.

13. The method of claim 12, wherein the seal comprises a first rubber layer coupling the seal to the first rim and a second rubber layer coupling the seal to the second rim.

14. The method of claim 13, wherein forming the seal comprises pressing the first and second rims together.

15. The method of claim 14, wherein forming the seal comprises heating the first and second rubber layers to bonding temperature while the seal is in contact with the first and second rims.

16. The method of claim 15, wherein the bonding temperature is at least 50° C.

17. The method of claim 15, wherein the first and second rubber layers comprise butyl rubber.

18. The method of claim 12, further comprising forming a layer of silicon adjacent to a wall of the seal opposite the volume, thereby sealing the wall from an outside atmosphere.

19. The method of claim 12, wherein the embedded ribbon oscillates between the sidewalls in a pattern.

20. The method of claim 19, wherein the pattern is at least one of a wave, a square wave, and a zig zag.

21. The method of claim 12, wherein the energy conversion unit is a light-to-electrical conversion unit.

22. A chamber for housing a light-to-electrical conversion unit comprising:
a housing comprising a first element and a second element forming a volume containing a light-to-electrical conversion unit, wherein the first and second elements define a shear plane;
an optical system coupled to the housing for focusing light beams onto the light-to-electrical conversion unit; and
a continuous rubber seal for sealing the first element to the second element, wherein the seal comprises an embedded wall in a plane parallel to the shear plane and extends along a length of the seal.

23. The chamber of claim 22, wherein the seal further comprises butyl rubber.

24. The chamber of claim 22, wherein the embedded wall comprises a metal.

25. The chamber of claim 24, wherein the metal is encased in a plastic.

26. The chamber of claim 22, further comprising:
a convex mirror coupled to the first element;
a concave mirror coupled to the second element and enclosing the convex mirror; and
an energy conversion unit contained in the volume and aligned in an optical path from the first element to the concave mirror, from the concave mirror to the convex mirror, and from the convex mirror to the light-to-electrical conversion unit.
